(19) United States
(12) Patent Application Publication
(10) Pub. No.: US 2015/0357433 A1
(43) Pub. Date: Dec. 10, 2015

(54) INTEGRATED CIRCUITS WITH VERTICAL JUNCTIONS BETWEEN nFETS AND pFETS, AND METHODS OF MANUFACTURING THE SAME

(71) Applicant: GLOBALFOUNDRIES, Inc., Grand Cayman (KY)

(72) Inventors: Hans-Peter Moll, Dresden (DE); Peter Baars, Dresden (DE)

(21) Appl. No.: 14/299,829

(22) Filed: Jun. 9, 2014

(51) Int. Cl. H01L 29/66; H01L 27/092; H01L 21/266

(52) U.S. Cl. CPC H01L 29/66545; H01L 21/266; H01L 27/092

(57) ABSTRACT

Integrated circuits and methods for producing the same are provided. A method for producing an integrated circuit includes forming an implant mask overlying a dummy gate, where the implant mask produces a masked dummy gate and an exposed dummy gate. Ions are implanted into the exposed dummy gate, and the implant mask is removed. The masked dummy gate is etched with an etchant selective to the masked dummy gate over the exposed dummy gate to form a trench, and the trench is filled with a conductive material.

### TECHNICAL FIELD

The technical field generally relates to integrated circuits and methods for manufacturing integrated circuits, and more particularly relates to integrated circuits with “N” and “P” field effect transistors having an essentially vertical junction wall between the “N” and “P” field effect transistors and methods of manufacturing such integrated circuits.

### BACKGROUND

The majority of present day integrated circuits (ICs) are implemented by using a plurality of interconnected field effect transistors (FETs), also called metal oxide semiconductor field effect transistors (MOSFETs or MOS transistors). A FET includes a gate electrode as a control electrode overlying a semiconductor substrate and spaced-apart source and drain regions in the substrate between which a current can flow. A gate insulator is disposed between the gate electrode and the semiconductor substrate to electrically isolate the gate electrode from the substrate. A control voltage applied to the gate electrode controls the flow of current through a channel in the substrate underlying the gate electrode between the source and drain regions. The FETs are generally “N” or “P” type FETs, (“nFET” or “pFET”) where the source and drain for nFETs are implanted with “N” type conductivity-determining ions, and the source and drain for pFETs are implanted with “P” type conductivity determining ions.

The gate electrode may be a replacement metal gate, where a temporary, sacrificial gate, which is called a “dummy” gate, is initially formed while other components of the FET are produced. In many cases, the dummy gate will extend for some distance in a straight line, and different FETs will be formed along that straight line. Part of the dummy gate is removed to form a trench, and a first replacement metal gate is formed in the trench so that is abuts the edge of the remaining dummy gate. The edge where the first replacement metal gate and the dummy gate meet forms a wall that is part of a gate junction wall. The remaining dummy gate is then removed, and a second replacement metal gate for an adjacent FET is formed to complete the gate junction wall. The gate junction wall forms part of a boundary between adjacent FETs, where one of the adjacent FETs may be an “N” type and the other a “P” type. The gate junction wall is often slanted such that there is an overhang. After the removal of the second, adjacent dummy gate discussed above, the overhand of the remaining first replacement metal gate may shield or block the deposition process for the second replacement metal gate. This shielding sometimes produces a void or gap in the second replacement metal gate at the gate junction wall. The void or gap in the replacement metal gate does not conduct electricity and degrades the performance of the FET with a gap at the gate. The etching process typically used to remove the dummy gate also etches or degrades the gate insulator somewhat.

Accordingly, it is desirable to provide integrated circuits and methods of manufacturing integrated circuits with a vertical gate junction wall to eliminate or reduce gaps in the replacement metal gates of adjoining FETS. In addition, it is desirable to provide integrated circuits and methods of forming them with a mild etching process that does minimal damage to the gate insulator. Furthermore, other desirable features and characteristics of the present embodiment will become apparent from the subsequent detailed description and the appended claims, taken in conjunction with the accompanying drawings and this background of the invention.

### BRIEF SUMMARY

Integrated circuits and methods for producing the same are provided. In an exemplary embodiment, a method for producing an integrated circuit includes forming an implant mask overlying a dummy gate, where the implant mask produces a masked dummy gate and an exposed dummy gate. Ions are implanted into the exposed dummy gate, and the implant mask is removed. The masked dummy gate is etched with an etchant selective to the masked dummy gate over the exposed dummy gate to form a trench, and the trench is filled with a conductive material.

A method for producing an integrated circuit is provided in another embodiment. An implant mask is formed overlying a dummy gate to produce a masked dummy gate and an exposed dummy gate. The etch resistance of the exposed dummy gate is increased, and the masked dummy gate is removed to produce a trench having a dummy gate junction wall. The dummy gate junction wall is within about 5 degrees of vertical.

An integrated circuit is provided in yet another embodiment. An nFET and a pFET include an N gate and a P gate, respectively. An active gate junction wall is positioned at a junction between the N gate and the P gate, where the active gate junction wall is within about 5 degrees of vertical.

### BRIEF DESCRIPTION OF THE DRAWINGS

The present embodiments will hereinafter be described in conjunction with the following drawing figures, wherein like numerals denote like elements, and wherein:

FIG. 1 is a sectioned perspective view of an exemplary embodiment of a portion of an integrated circuit; and

FIGS. 2-12 illustrate portions of an integrated circuit and methods for its fabrication in accordance with exemplary embodiments, where FIGS. 2-4, 8, and 11-13 are sectional views along a plane A-A from FIG. 1, FIGS. 5, 7, 9, and 14 are sectional views along a plane B-B from FIG. 1, and FIGS. 6 and 10 are perspective sectional views of the integrated circuit.

### DETAILED DESCRIPTION

The following detailed description is merely exemplary in nature and is not intended to limit the various embodiments or the application and uses thereof. Furthermore, there is no intention to be bound by any theory presented in the preceding background or the following detailed description.

According to various embodiments described herein, a pFET and an nFET are formed from an extended, shared dummy gate overlying a substrate. An insulating layer is formed overlying the dummy gate and substrate, and then partially removed by chemical mechanical planarization to expose the top of the dummy gate. An implant mask is formed over one of the pFET or nFET, such as with photoresist, to create a masked dummy gate underlying the etch mask and an exposed dummy gate that is not underlying the etch mask. The exposed dummy gate is implanted with ions to increase its etch resistance, but the etch mask prevents most of the ions from implanting in the masked dummy gate. The implant mask is removed after the ions are implanted. The masked dummy gate is etched with a selective etchant that removes the masked dummy gate much faster than the exposed dummy gate that is implanted ions. The ions can be implanted such that an essentially vertical dummy gate junction wall is formed at the intersection of a trench where the masked dummy gate was and where the exposed dummy gate remains. A wet etchant can be used to remove the masked dummy gate, where the wet etchant does very little damage to a gate dielectric underlying the dummy gate. The trench can be filed with a replacement metal gate, which is then protected with an etch mask, and the exposed dummy gate can be removed and replaced with a replacement metal gate.

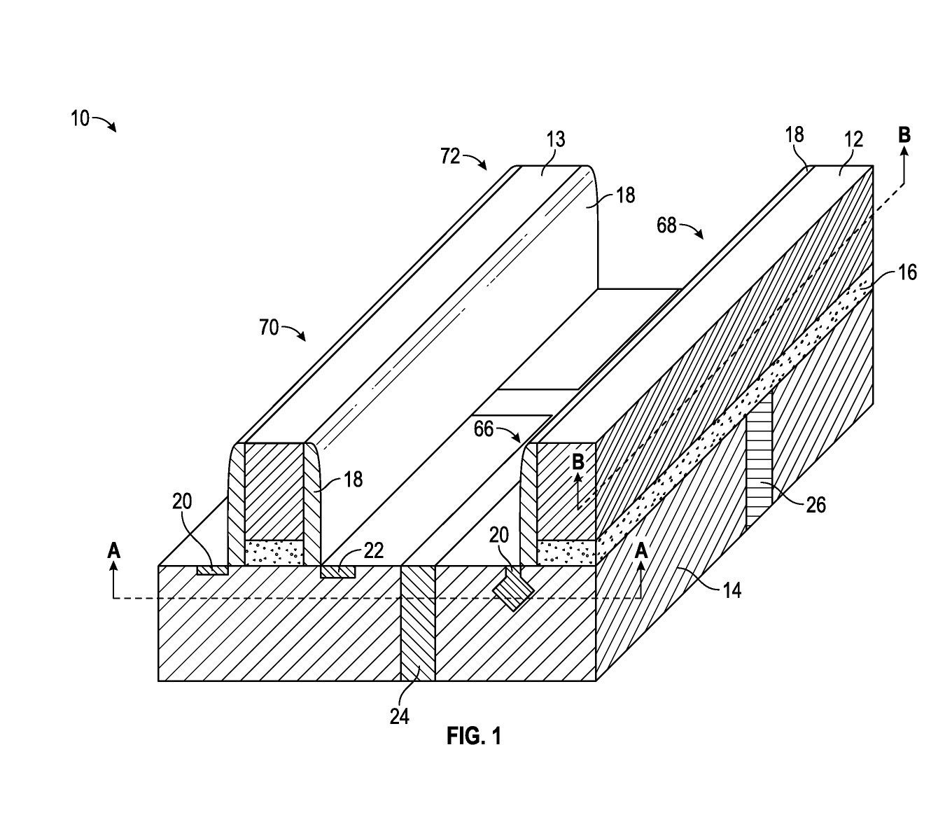

An exemplary embodiment is illustrated in FIG. 1, where FIG. 1 is sectioned along plane A-A and plane B-B, which intersect at a right angle. An integrated circuit 10 includes a sacrificial first dummy gate 12 and second dummy gate 13 formed overlying a substrate 14. As used herein, the term “substrate” 14 will be used to encompass semiconductor materials conventionally used in the semiconductor industry from which to make electrical devices. Semiconductor materials include monocrystalline silicon materials, such as the relatively pure or lightly impurity-doped monocrystalline silicon materials typically used in the semiconductor industry, as well as polycrystalline silicon materials, and silicon admixed with other elements such as germanium, carbon, and the like. Semiconductor material also includes other materials such as relatively pure and impurity-doped germanium, gallium arsenide, zinc oxide, glass, and the like. In an exemplary embodiment, the substrate 14 is a monocrystalline silicon material. The silicon substrate 14 may be a bulk silicon wafer (as illustrated) or may be a thin layer of silicon on an insulating layer (commonly known as silicon-on-insulator or SOI) that, in turn, is supported by a carrier wafer.

In an exemplary embodiment, the first and second dummy gates 12, 13 are polysilicon formed overlying a gate dielectric 16, where the gate dielectric 16 overlies the substrate 14. The gate dielectric 16 is a dielectric material with a high dielectric constant, such as hafnium oxide (HfO₂) or hafnium silicon oxynitride (HfSiON). A “high” dielectric constant is about 3.7 or more in some embodiments, but other types of dielectric materials can be used in the gate dielectric 16 in alternate embodiments. A titanium nitride (TiN) cap (not illustrated) may optionally be positioned between the high dielectric constant material and the first and second dummy gates 12, 13 where the cap is part of the gate dielectric 16. The height of the first and second dummy gates 12, 13 measured from the gate dielectric 16 is from about 30 nanometers to about 50 nanometers thick in some embodiments, or from about 20 nanometers to about 100 nanometers thick in other embodiments, but other thicknesses are also possible. A spacer 18 is positioned on opposite sides of the first and second dummy gates 12, 13 where the spacer 18 is also overlying the substrate 14. The spacer 18 may include silicon nitride in an exemplary embodiment. A source 20 and a drain 22 may be formed in the substrate 14 self-aligned to the spacers 18 on the sides of the first and second dummy gates 12, 13, where the source 20 and drain 22 are implanted with “N” type conductivity-determining ions or “P” type conductivity-determining ions for an nFET or a pFET, respectively. “N” type conductivity-determining ions primarily include ions of phosphorous, arsenic, and/or antimony, but other materials could also be used. “P” type conductivity-determining ions primarily include boron, aluminum, gallium, and indium, but other materials could also be used. The source 20 and drain 22 for an nFET are illustrated as rectangles, and the source 20 and drain 22 for the pFET are illustrated as diamonds.

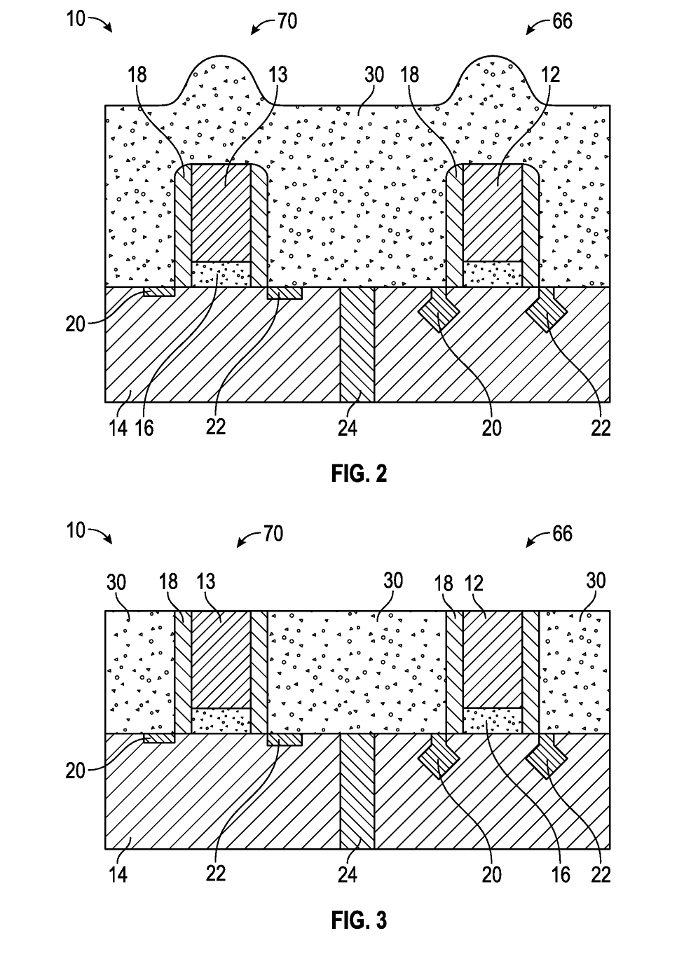

A shallow trench isolation 24 extends into the substrate 14 between the first dummy gate 12 and the second dummy gate 13 to electrically isolate adjacent devices. In an exemplary embodiment, the shallow trench isolation 24 includes an insulating material such as silicon dioxide. While only two dummy gates are shown in FIG. 2, it will be appreciated that the integrated circuit 10 may include a plurality of dummy gates running parallel to each other, where one or more of the dummy gates may extend for a sufficient distance so that more than one FET can be formed on a single extended dummy gate. In an exemplary embodiment, a gate isolation area 26 is formed in the substrate 14 underlying the first and second dummy gates 12, 13, where the gate isolation area 26 is positioned underlying a transition area between a pFET and an nFET along a single dummy gate. The gate isolation area 26 may be a dielectric material, such as silicon dioxide or silicon nitride. The integrated circuit 10 illustrated in FIG. 1 has four FETs, including a first pFET 66 on the front part of the first dummy gate 12, a second nFET 68 on the rear part of the first dummy gate 12, a third nFET 70 on the front part of the second dummy gate 13, and a fourth pFET 72 on the rear part of the second dummy gate 13. References to the “front” and “rear” of the first and second dummy gates 12, 13 refer to the relative position in the embodiment illustrated in FIG. 1, and are not intended to limit this description to any relative positions or orders. Other positions or relative positions of the FETs are possible in alternate embodiments.

The substrate 14, first and second dummy gates 12, 13, gate dielectric 16, spacers 18, source 20 and drain 22, shallow trench isolation 24, and gate isolation area 26 may be formed in a wide variety of manners, as understood by those skilled in the art, and the manner of producing these components is not critical to this description. Many different embodiments of the substrate 14, first and second dummy gates 12, 13, gate dielectric 16, spacers 18, source 20 and drain 22, shallow trench isolation 24, and gate isolation area 26 may be used.

Reference is made to FIG. 2, where FIG. 2 is a sectional view along plane A-A from FIG. 1. An insulating layer 30 is formed overlying the first and second dummy gates 12, 13 and the substrate 14, where the insulating layer 30 can be a wide variety of insulating materials. In an exemplary embodiment, the insulating layer 30 is silicon dioxide formed by a high density plasma using silane and oxygen, but other raw materials or other insulating materials are also possible in alternate embodiments. A portion of the insulating layer 30 is then removed, as illustrated in the exemplary embodiment in FIG. 3, to expose a top surface of the first and second dummy gates 12, 13 and a top surface of the spacers 18. Chemical mechanical planarization can be used to remove the portion of the insulating layer 30.

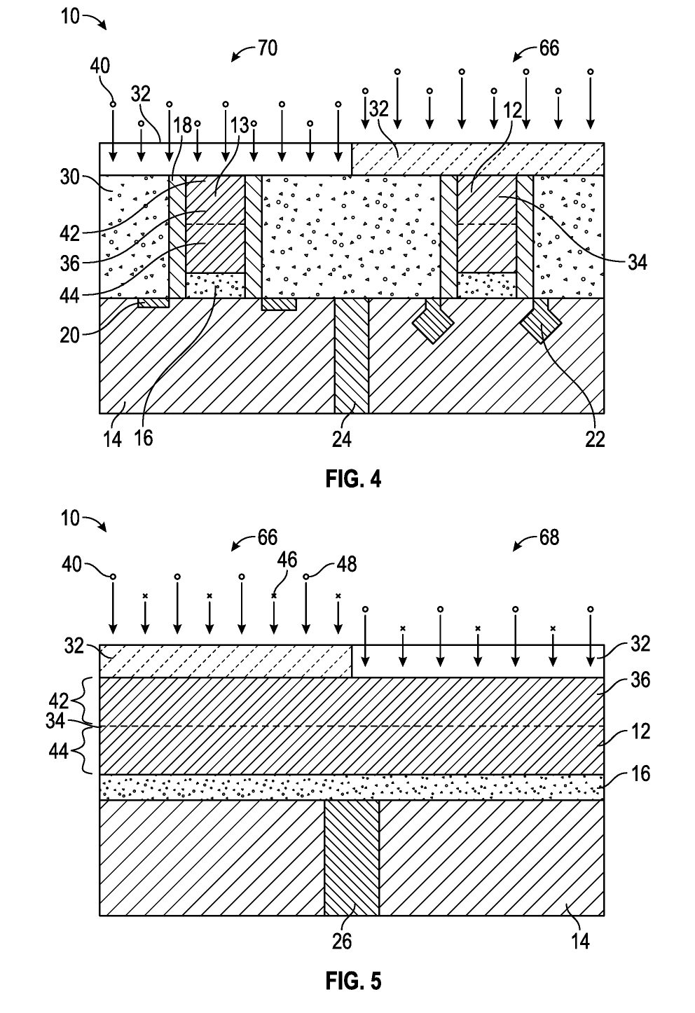

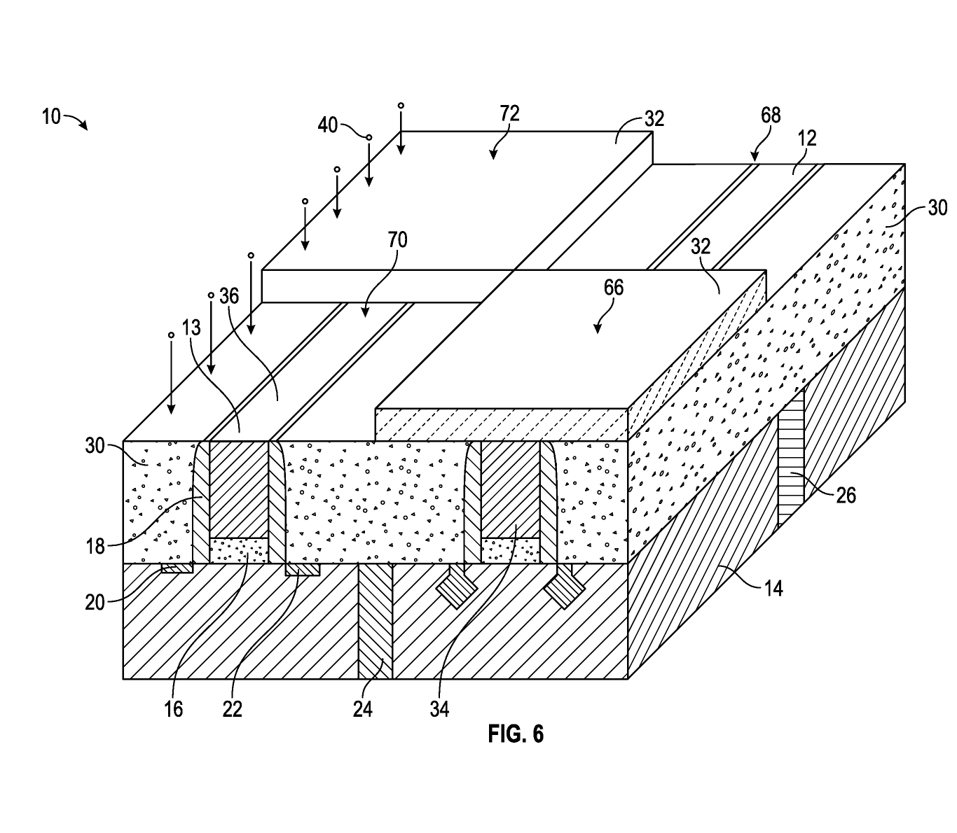

Reference is now made to FIGS. 4-6, where FIG. 4 is a sectional view along plane A-A from FIG. 1, FIG. 5 is a sectional view along plane B-B from FIG. 1, and FIG. 6 is a perspective sectional view of the integrated circuit 10. An implant mask 32 is formed overlying the part of the first dummy gate 12 associated with the first pFET 66, and also overlying the part of the second dummy gate 13 associated with the fourth pFET 72, such that the implant mask 32 overlies the dummy gates for the pFETs. The implant mask 32 creates a masked dummy gate 34 underlying the implant mask 32, and an exposed dummy gate 36 that is not underlying the implant mask 32. In the embodiment illustrated, the masked dummy gates 34 are associated with pFETs, and the exposed dummy gates 36 are associated with nFETs. The implant mask 32 is a photoresist layer in an exemplary embodiment, but the implant mask 32 may include a hard mask (not illustrated) or other components in alternate embodiments. The photoresist layer is patterned and etched to form the implant mask 32. The edge of the implant mask 32, which is directly above the intersection of the exposed dummy gate 36 and the masked dummy gate 34, may overlie the gate isolation area 26, as best seen in FIG. 5. The edge of the implant mask 32 may also be at a transition point between an nFET and a pFET along a single dummy gate, such as the transition point between the first pFET 66 and the second nFET 68 along the first dummy gate 12. FIGS. 5 and 6 illustrate the implant mask 32 over the pFETs, but the implant mask 32 could also overlie the nFETs in alternate embodiments.

Ions 40 are implanted into the exposed dummy gates 36, but the implant mask 32 blocks the ions 40 from being implanted into the masked dummy gate 34. The exposed dummy gates 36 become less susceptible to etching as the concentration of embedded ions increases, so some implanted ions 40 may be desired throughout the depth of the exposed dummy gates 36. The ions 40 may be implanted at a plurality of different energies, where ions implanted at higher energies tend to become embedded deeper in the exposed dummy gate 36, so the ions 40 are implanted at a plurality of depths within the exposed dummy gate 36. In an exemplary embodiment, the ions 40 are implanted at a first energy such that the ions are embedded in a top half 42 of the exposed dummy gate 36, and the ions 40 are implanted at a second energy such that the ions are embedded in a bottom half 44 of the exposed dummy gate 36. The second energy may be higher than the first energy. The ions 40 may also be implanted at a plurality of different energies such that ions 40 are implanted throughout the depth of the exposed dummy gate 36, or at a plurality of depths within the exposed dummy gate 36. The insulating layer 30 and the spacers 18 still function as insulators after the ions 40 are imbedded in the exposed dummy gate 36, even though some ions 40 may be embedded in the insulating layer 30 and the spacers 18.

In some embodiments, the ions 40 include a first ion 46 and a second ion 48, where the first ion 46 is embedded in the top half 42 of the exposed dummy gate 36 and the second ion 48 is embedded in the bottom half 44 of the exposed dummy gate. FIG. 5 illustrates an embodiment have a plurality of different ions 40, including a first ion 46 and a second ion 48, where FIG. 4 illustrates an embodiment where a single type of ion 40 is used. The first ion 46 is boron and the second ion 48 is carbon in an exemplary embodiment, but a wide variety of other ions could be used as long as the first and second ions 46, 48 are different from each other. The first ion 46 and the second ion 48 are selected to increase the etch resistance of the exposed dummy gate 36, so the selection of the ion(s) 40 is adjusted to the material of the dummy gate and the etchant to be used. For example, boron ions may increase the etch resistance of polysilicon, but boron ions that pass completely through the exposed dummy gate 36 and enter the gate dielectric 16 may impair the functionality of the gate dielectric 16. The depth of ion implantation is not precise, so the second ion 48 can be selected to increase the etch resistance of the exposed dummy gate 36 but not to damage the functionality of the gate dielectric 16. A compound that does not significantly increase electrical conductance when embedded is referred to as a “neutral” compound, and a neutral compound such as carbon may be selected for the second ion 48 to minimize potential damage to the gate dielectric 16. An ion 40 that provides higher etch resistance may be selected for the first ion 46, because the lower first implantation energy is set to embed the first ion 46 in the top half 42 of the exposed dummy gate 36 so there is little chance of the first ion 46 passing through the exposed dummy gate 36 and becoming embedded in the gate dielectric 16. In some embodiments, more than two ions 40 can be used, and the implantation energies can be selected to implant each ion 40 at a desired level of the exposed dummy gate 36. The implantation energy will vary with the selected ion 40 and the desired depth of implantation, where implantation energies from about 20 kilo electron volts to about 100 kilo electron volts may be used in some embodiments.

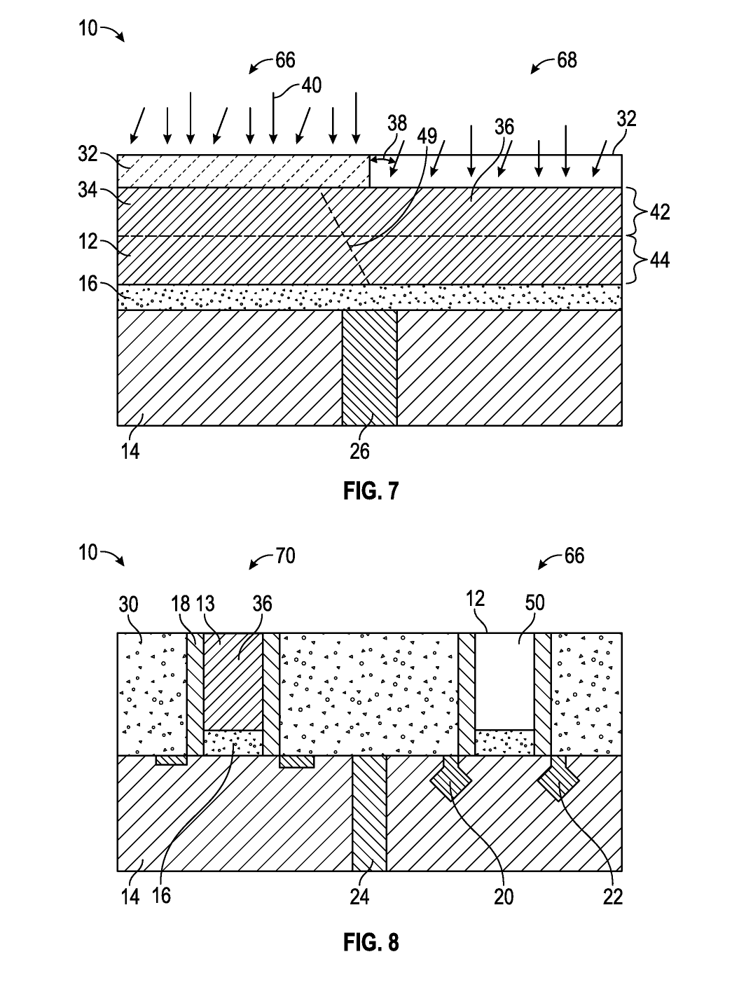

In the exemplary embodiment illustrated in FIG. 7, some ions 40 are implanted at an angle 38 other than a right angle, relative to the surface of the exposed dummy gate 36, such that some of the ions 40 are implanted in the first dummy gate 12 underlying the implant mask 32, which is the masked dummy gate 34. The ions 40 implanted at an angle 38 may be implanted at the first energy, where the first energy is lower than the second energy, so the ions 40 are implanted at a short, controlled distance within the masked dummy gate 34. A dashed line 49 indicates the boundary separating the part of the first dummy gate 12 that is implanted with ions 40, and the part that is not implanted with ions 40. The ions 40 may penetrate the edge of the implant mask 32 at the point where it contacts the first dummy gate 12, so the ions 40 may be implanted in some areas of the masked dummy gate 34 that are “shaded” by the implant mask 32. As such, the implanted area of the first dummy gate 12 may form an angled line represented by the dashed line 49 that extends from about a point directly underlying the edge of the implant mask 32 at the bottom of the first dummy gate 12 to a point underlying the implant mask 32 at the top of the first dummy gate 12. The embodiment illustrated in FIG. 7 also applies to dummy gates other than the first dummy gate 12.

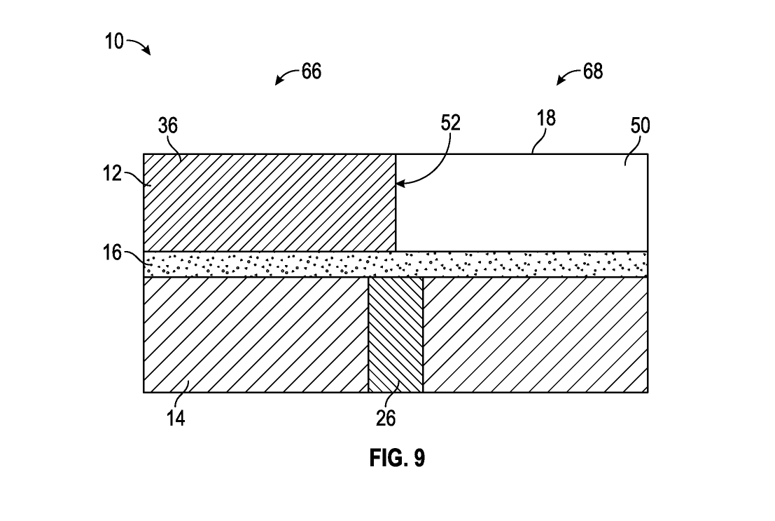

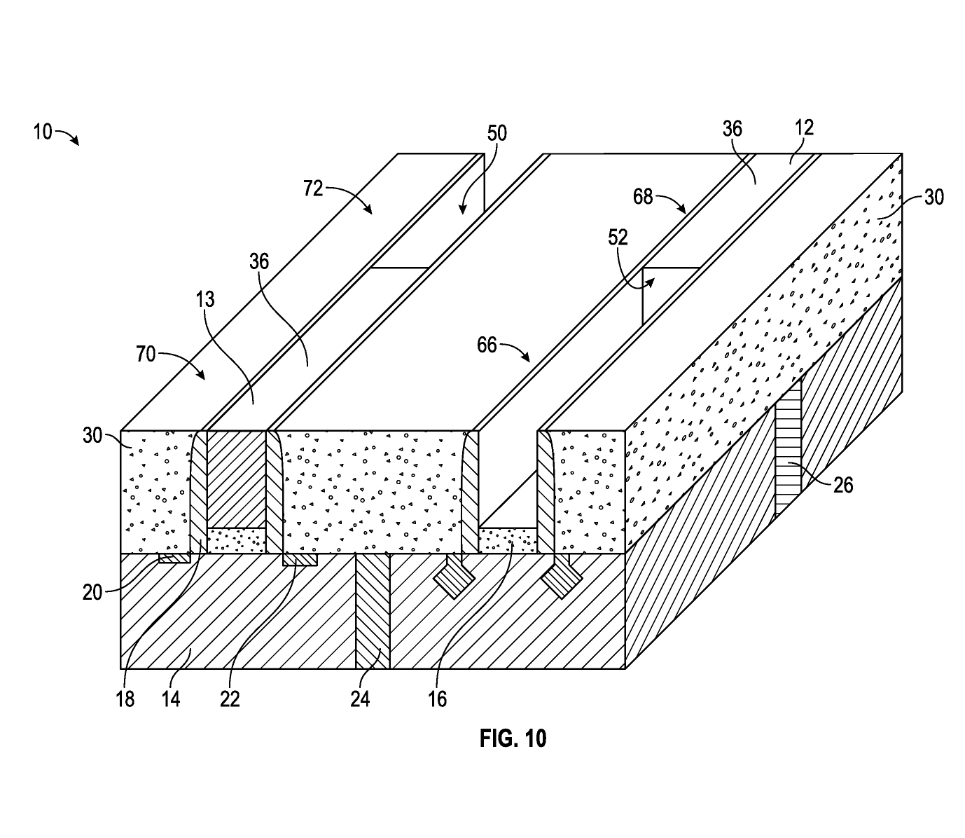

The implant mask 32 is removed after the ions 40 are implanted, such as with an oxygen containing plasma, and the masked dummy gate 34 is removed, as illustrated in an exemplary embodiment in FIGS. 8-10, with continuing reference to FIG. 7, where FIG. 8 is a sectional view along plane A-A of FIG. 1, FIG. 9 is a sectional view along plane B-B of FIG. 1, and FIG. 10 is a perspective sections view of the integrated circuit 10. The masked dummy gates 34 are removed with a liquid etchant in an exemplary embodiment, where the etchant is selective to the material of the masked dummy gate 34 over the material of the exposed dummy gate 36. The masked dummy gate 34 is the dummy gate for the first pFET 66 and for the fourth pFET 72, as described above. In one example, an ammonia etchant with hydroxyl compounds may etch polysilicon without implanted ions about 50 to about 100 times faster than polysilicon with implanted ions. In an exemplary embodiment the masked dummy gate 34 includes polysilicon without implanted ions and the exposed dummy gate 36 includes polysilicon with implanted ions, as mentioned above. A wide variety of materials can be used to provide hydroxyl compounds to the etchant, such as potassium hydroxide. A trench 50 is formed where the masked dummy gate 34 is removed.

The liquid etchant may etch the material of the exposed dummy gate 36 somewhat, but at a slower rate than the material of the masked dummy gate 34. The liquid etchant begins to etch the dummy gate at the surface, so as the upper layers of the masked dummy gate 34 are removed the liquid etchant contacts the side surface of the exposed dummy gate 36. As the liquid etchant removes more of the masked dummy gate 34, the etchant contacts deeper layers on the side surface of the exposed dummy gate 36. The uppermost layers on the side surface of the exposed dummy gate 36 are exposed to the liquid etchant for the longest period of time, and the deepest layers are only exposed for a brief time in comparison to the upper layers. Therefore, the liquid etchant could produce an angled line at the intersection of the trench 50 and the exposed dummy gate 36 if all the ions 40 were implanted vertically into the exposed dummy gate 36. The ions 40 implanted at an angle 38 into the upper layers of the masked dummy gate 34 (up to dashed line 49) reduce the etch rate of those upper layers, so the intersection of the trench 50 and the side surface of the exposed dummy gate 36 is about vertical. In this description, the intersection of the trench 50 and the side surface of the exposed dummy gate 36 is called a “dummy gate junction wall,” and is indicated by reference number 52.

The angle 38 and energy of the implanted ions 40 can be adjusted to provide an essentially vertical dummy gate junction wall 52, where essentially vertical is within about 5 degrees of vertical in some embodiments, or within about 3 degrees of vertical, or within about 2 degrees of vertical, or within about 1 degree of vertical in other embodiments. The ions 40 may be implanted throughout the depth of the exposed dummy gate 36, so the etch rate of the exposed dummy gate 36 does not change significantly as lower and lower layers of the masked dummy gate 34 are removed. The first and second ions 46, 48 are implanted in the top and bottom half 42, 44 of the exposed dummy gate 36, respectively, in one embodiment. Different ions 40 may impart different degrees of etch resistance, so the concentration of the different ions 40 can be adjusted to provide a relatively constant etch rate for different depths of the exposed dummy gate 36. Different depths of the exposed dummy gate 36 may have somewhat different etch rates, so the dummy gate junction wall 52 may not be perfectly straight, but it still remains essentially vertical.

The titanium nitride cap on the top of the gate dielectric 16 that was mentioned above (not illustrated) may protect the gate dielectric 16 from the liquid etchant in some embodiments. The liquid etchant is relatively mild compared to a dry reactive ion etch, and the liquid etchant may do less damage to the gate dielectric 16 than a reactive ion etch. Therefore, the depth and composition of the gate dielectric 16 does not change during the liquid etching step as much as it would during a reaction ion etch.

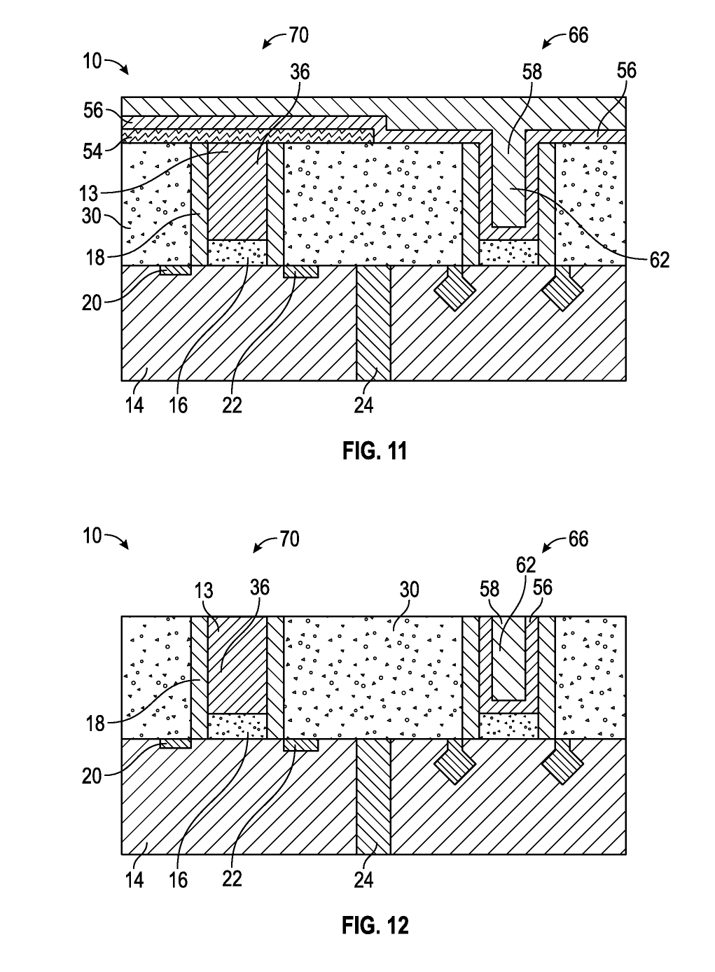

Referring to the exemplary embodiment illustrated in FIG. 11, an etch mask 54 may be formed over the exposed dummy gate 36. The etch mask 54 may be silicon dioxide, and photoresist (not illustrated) can be used to pattern the etch mask 54 to overlie the exposed dummy gate 36, as is well known in the art. The trench 50 is then filled with a conductive material to form a replacement metal gate. In an exemplary embodiment, a working layer 56 is be deposited within the trench 50 and overlying the insulating layer 30 and the etch mask 54. The working layer 56 may be formed of several layers of different materials, such as tantalum nitride, then titanium nitride, and then another layer of tantalum nitride. The working layer 56 is be deposited by chemical vapor deposition or atomic layer deposition, but other types of working layers 56 are used in alternate embodiments. A conductive core 58 is formed overlying the working layer 56, where the core 58 is formed from many different conductive components in various embodiments. For example, an aluminum core 58 may be deposited by chemical vapor deposition using triisobutylaluminium. The first replacement metal gate 62 formed is a P gate in the embodiment illustrated, but the first replacement metal gate 62 formed could be an N gate in alternate embodiments. In this description, the N gate is the gate for an nFET, and the P gate is the gate for the pFET.

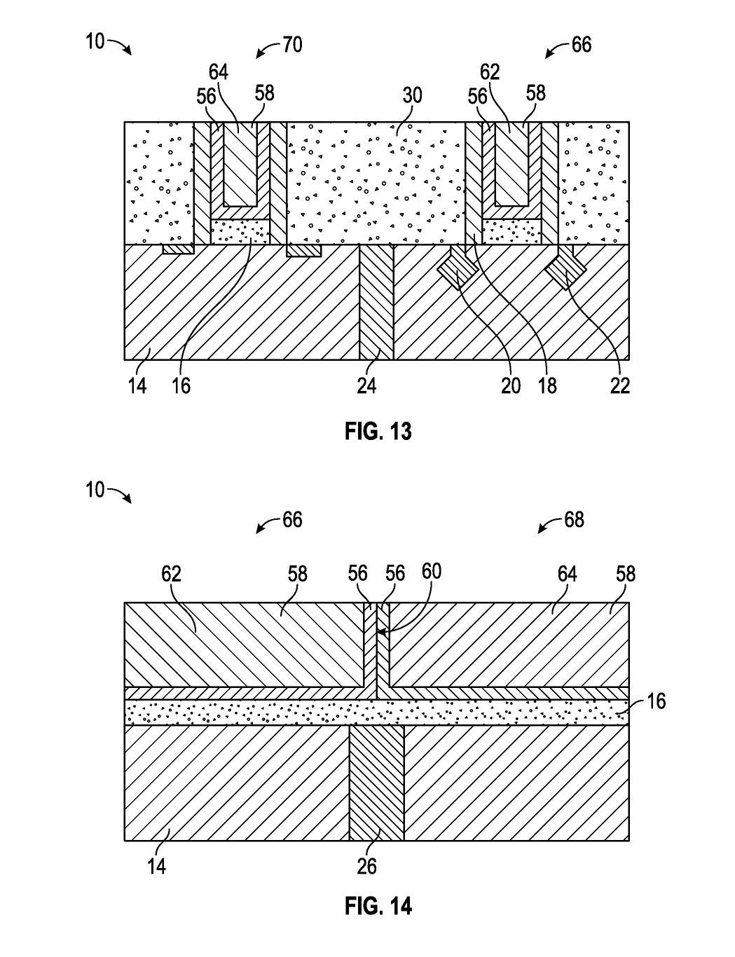

The overburden and the etch mask 54 are removed by chemical mechanical planarization, as illustrated in an exemplary embodiment in FIG. 12. After the overburden and etch mask 54 are removed, the top surface of the exposed dummy gate 36 is exposed. Referring to FIG. 13, the exposed dummy gate 36 is removed, such as with a reactive ion etch, and a second replacement metal gate 64 can be formed in the trench vacated by the exposed dummy gate 36, as described above and as understood by those skilled in the art. The second replacement metal gate 64, which is formed in the previous location of the exposed dummy gate 36 and is the N gate in the embodiment illustrated, may have the same or a different working layer 56 and/or core 58 than the first replacement metal gate 62, which was formed in the previous location of the masked dummy gate 34 and is the P gate in the embodiment illustrated.

Referring now to FIG. 14, which is taken along plane B-B from FIG. 1, an active gate junction wall 60 is formed in the place of the dummy gate junction wall 52 mentioned above and illustrated in FIGS. 9 and 10. The active gate junction wall 60 is at the junction between the N gate and the P gate. The active gate junction wall 60 is positioned overlying the gate isolation area 26, and the active gate junction wall 60 separates the first pFET 66 and the second nFET 68 (or other pFETs and nFETs). The active gate junction wall 60 is within about 5 degrees of vertical, or within about 3 degrees of vertical, or within about 2 degrees of vertical, or within about 1 degree of vertical in various embodiments, because the active gate junction wall 60 is formed at the location of the dummy gate junction wall 52 described above. The first pFET 66 and second nFET 68 (and other FETs) can then be incorporated into an integrated circuit 10, as understood by those skilled in the art.

While at least one exemplary embodiment has been presented in the foregoing detailed description, it should be appreciated that a vast number of variations exist. It should also be appreciated that the exemplary embodiments are only examples, and are not intended to limit the scope, applicability, or configuration of the application in any way. Rather, the foregoing detailed description will provide those skilled in the art with a convenient road map for implementing one or more embodiments, it being understood that various changes may be made in the function and arrangement of elements described in an exemplary embodiment without departing from the scope, as set forth in the appended claims.

What is claimed is:

1. A method of producing an integrated circuit comprising:
forming an implant mask overlying a portion of a dummy gate to produce a masked dummy gate and an exposed dummy gate;
implanting ions into the exposed dummy gate;
removing the implant mask;
etching the masked dummy gate with an etchant that selectively etches the masked dummy gate over the exposed dummy gate to form a trench; and
filling the trench with a conductive material.

2. The method of claim 1 wherein implanting the ions comprises implanting the ions at a plurality of different energies such that the ions are embedded at a plurality of depths in the exposed dummy gate.

3. The method of claim 1 wherein implanting the ions comprises implanting a first ion within a top half of the exposed dummy gate; and
implanting a second ion within a bottom half of the exposed dummy gate, wherein the first ion is different than the second ion.

4. The method of claim 1 wherein etching the masked dummy gate comprises etching the masked dummy gate with a liquid etchant.

5. The method of claim 4 wherein etching the masked dummy gate comprises etching the masked dummy gate with the liquid etchant, wherein the liquid etchant comprises ammonia.

6. The method of claim 1 wherein implanting the ions into the exposed dummy gate comprises implanting the ions at an angle such that some ions are implanted into the masked dummy gate.

7. The method of claim 6 wherein implanting the ions into the exposed dummy gate comprises implanting the ions at the angle with a first energy such that some of the ions are implanted into a top half of the masked dummy gate; and
wherein implanting the ions into the exposed dummy gate comprises implanting the ions into the exposed dummy gate at a second energy higher than the first energy.

8. The method of claim 7 wherein etching the masked dummy gate comprises etching the masked dummy gate to form the trench having a dummy gate junction wall within about 5 degrees of vertical.

9. The method of claim 1 further comprising:
forming an insulating layer overlying the dummy gate and a substrate;
removing a portion of the insulating layer to expose a top of the dummy gate; and
wherein forming the implant mask comprises forming a photoresist layer overlying the masked dummy gate.

10. A method of producing an integrated circuit comprising:
forming an implant mask overlying a dummy gate to produce a masked dummy gate and an exposed dummy gate, wherein the implant mask overlies the masked dummy gate;
increasing an etch resistance of the exposed dummy gate; and
removing the masked dummy gate to produce a trench having a dummy gate junction wall, wherein the dummy gate junction wall is within about 5 degrees of vertical.

11. The method of claim 10 wherein increasing the etch resistance of the exposed dummy gate comprises implanting ions in the exposed dummy gate.

12. The method of claim 11 wherein implanting the ions in the exposed dummy gate comprises implanting the ions at an angle such that some of the ions are implanted into the masked dummy gate.

13. The method of claim 12 wherein implanting the ions in the exposed dummy gate comprises:
implanting the ions at the angle at a first energy such that some of the ions are implanted in the masked dummy gate; and
implanting the ions in the exposed dummy gate at a second energy higher than the first energy.

14. The method of claim 11 wherein implanting the ions comprises implanting a first ion at a first energy into a top half of the exposed dummy gate, and implanting a second ion at a second energy into a bottom half of the exposed dummy gate.

15. The method of claim 10 wherein removing the masked dummy gate comprises etching the masked dummy gate with an etchant selective to a material of the masked dummy gate over the material of the exposed dummy gate.

16. The method of claim 10 wherein removing the masked dummy gate comprises etching the masked dummy gate with a liquid etchant.

17. The method of claim 16 where removing the masked dummy gate comprises etching the masked dummy gate with the liquid etchant, wherein the liquid etchant comprises ammonia.

18. The method of claim 10 wherein forming the implant mask comprises forming a photoresist layer overlying the masked dummy gate.

19. The method of claim 10 further comprising:
removing the implant mask prior to removing the masked dummy gate.

20. An integrated circuit comprising:
an nFET and a pFET, wherein the nFET comprises an N gate and the pFET comprises a P gate; and
an active gate junction wall positioned at a junction between the N gate and the P gate, wherein the active gate junction wall is within about 5 degrees of vertical.
